(19) United States
(12) Patent Application Publication
(10) Pub. No.: US 2024/0313081 A1
(43) Pub. Date: Sep. 19, 2024

(54) Low Leakage Replacement Metal Gate FET

(71) Applicant: Murata Manufacturing Co., Ltd., Kyoto (JP)

(72) Inventors: Jagar Singh, Clifton Park, NY (US); Simon Edward Willard, Irvine, CA (US)

(21) Appl. No.: 18/185,285

(22) Filed: Mar. 16, 2023

(51) Int. Cl. H01L 29/49; H01L 21/28; H01L 21/84; H01L 27/12; H01L 29/66; H01L 29/78

(52) U.S. Cl. CPC H01L 29/4966; H01L 21/28088; H01L 21/84; H01L 27/1203; H01L 29/66545; H01L 29/7838

(57) ABSTRACT

FET designs, and in particular NMOSFET designs based on SOI fabrication technology, that exhibit low leakage in the presence of the edge transistor phenomenon. Embodiments include FETs in which the threshold voltage V_{TE} of the edge FETs is increased to a level that is at least equal to the threshold voltage V_{TC} of the central conduction channel FET using a novel dual work function configuration of a high dielectric constant (high-κ) replacement metal gate (RMG) structure. One embodiment encompasses a FET including an RMG structure overlying a doped silicon region, the RMG structure including: an interface insulator formed over the doped silicon region; a high-κ material formed over the interface insulator; an N-type work function material overlaying and in contact with a central portion of the high-κ material; and a P-type work function material overlaying and in contact with at least one edge portion of the high-κ material.

### BACKGROUND

### (1) Technical Field

This invention relates to transistor devices, and more particularly to low-leakage field effect transistors.

### (2) Background

Many (if not most) modern electronic systems are based on field-effect transistors (FETs) fabricated as part of integrated circuits (ICs). Accordingly, improving the performance of FETs, particularly as FET structures within ICs shrink to ever smaller dimensions, is of importance to the electronics industry. In the fabrication of FET structures within ICs, silicon-on-insulator (SOI) substrates have many benefits over bulk silicon substrates, including higher speed, lower power consumption, improved radio frequency (RF) performance, and improved radiation resistance. For many IC applications, dielectrically-isolated CMOS FETs are the preferred transistor and logic structure due to their scalability, low power, and design flexibility. In dielectrically-isolated CMOS, N-type and P-type MOSFETs are isolated laterally from each other by fabricating each one in its own silicon island. Typically, this isolation is provided by etching the silicon film of an SOI substrate into spaced-apart islands and backfilling the gaps between such islands with deposited dielectric (e.g., silicon dioxide, SiO₂), although in the early days of SOI, isolation through local oxidation of the silicon regions between transistors (also known as LOCOS isolation) had been widely used.

FIG. 1A is a top plan view of the layout of a typical prior art N-type MOSFET (“nFET”) 100 based on SOI fabrication technology. In the illustrated example, an island of P-type silicon 102 defining an Si Active Region (see FIGS. 1B and 1C) is formed in conventional fashion (e.g., by diffusion of boron) on an SOI substrate (see FIGS. 1B and 1C) and surrounded by SiO₂ 104 by backfilling or LOCOS isolation. A gate structure 106 comprising an insulator (e.g., an oxide layer) and overlaying gate material (e.g., polysilicon) is formed over the silicon island 102. The gate structure 106 has a length L parallel to the X dimension and in the X-Y plane of the SOI substrate. The width of the nFET 100 is parallel to the Y dimension and in the X-Y plane of the SOI substrate.

An N-type source region 108 and drain 110 region are formed by implanting or diffusing N+ material (e.g., phosphorus, arsenic) within a masked implant area 111 formed over the silicon island 102 (note that the masked implant area 111 used to define the source 108 and drain 110 N+ implant regions may overlap the SiO₂ surrounding the silicon island 102). Accordingly, the gate structure 106 is self-aligned with respect to the source 108 and drain 110 regions and defines a conduction channel 113 between the source 108 and drain 110 regions. Electrically conductive contacts 112, 114 are respectively made to the source 108 and drain 110 regions. Other common structures (e.g., device interconnects, gate contacts, etc.) are omitted for clarity.

FIG. 1B is a cross-sectional view of the nFET 100 along line A-A of FIG. 1A. FIG. 1C is a cross-sectional view of the nFET 100 along line B-B of FIG. 1A. Both figures show additional structural details of the nFET 100 (note that the dimensions of various elements are not to scale). The N-type source implantation region 108, the self-aligned gate structure 106, and the N-type drain implantation region 110 are formed in the Si Active Region 102 within a region further defined by isolation structures 120. The isolation structures 120 may be, for example, shallow trench isolation (STI) structures formed from, for example, SiO₂ processing using CVD (chemical vapor deposition) or high density plasma techniques. The gate structure 106 overlies a doped Si region 122 (P-type in this example) within the Si Active Region 102 and comprises an insulator (e.g., an SiO₂ layer) 124 and overlaying gate material 126 (e.g., N+ or P+ polysilicon, or a replacement metal gate—see FIGS. 3A and 3B below). Offset spacers 128 along the sides of the gate structure 106 may also be formed as part of the fabrication process for making the gate structure 106. A salicide (self-aligned silicide) layer (not shown) may be formed over the gate structure 106.

In the illustrated example, the Si Active Region 102 is formed on a buried oxide (BOX) layer 130 formed on top of a substrate 132, such as a silicon substrate (the BOX layer 130 and substrate 132 are omitted from FIG. 1C to reduce clutter). The BOX layer 130 and Si Active Region 102 may be considered to be a substructure 134 formed on the substrate 132. A superstructure (not shown) may be fabricated on top of the substructure 134 to complete the IC. A superstructure may include, for example, conductive vias, insulating layers (dielectrics), metallization layers, and electrical contacts (pads) for die-to-package connections. For example, FIGS. 1B and 1C show stylized electrically conductive contacts S, G, and D made to the source region 108, the gate structure 106, and the drain region 110, respectively, and would be fabricated as part of the IC superstructure.

FIG. 2 is a perspective view of an nFET 200 similar to the nFET 100 of FIG. 1A (again, the dimensions of various elements are not to scale). Elements in common with the nFET 100 of FIG. 1A bear the same reference numbers. The length L of the gate structure 106 is parallel with the X dimension of the nFET 200 and the width W is parallel with the Y dimension of the nFET 200. The length L is generally substantially less than the width W. Thus, it should be appreciated that the Y-dimension width of the FET cross-section in FIG. 1C is greater than the X-dimension width of the FET cross-section in FIG. 1B—that is, the scales in FIGS. 1B and 1C are not equivalent.

The nFET 100 may be operated as an electrical switch by applying a gate-source voltage, V_{GS}, to the gate structure 106 sufficiently positive to turn the transistor ON, thereby creating a low impedance current path between the source region 108 and the drain region 110 through the conduction channel 113. The nFET 100 may be turned OFF by applying a V_{GS} to the gate structure 106 at a voltage less than the threshold voltage, V_{T}, of the device, thereby creating a high impedance path between the source region 108 and the drain region 110. In other applications, the nFET 100 may be operated as a variable-resistance device having an output modulated by a signal (e.g., a radio frequency signal) applied to the gate structure 106.

As is known in the art, P-type enhancement mode MOSFETs (pFETs) have a similar structure, but with different doping characteristics, as do N-type and P-type depletion mode MOSFETS. Complementary metal-oxide-semiconductor (CMOS) devices use pairs of P-type and N-type MOSFETs, which may be either enhancement mode or depletion mode structures. The multiple steps needed for making elements and features of the MOSFET 100 structure, such as masking, doping (via implanting, diffusion, etc.), epitaxial growing, cleaving, polishing, etc., are well known in the art.

With technology scaling to smaller FET device dimensions (e.g., at 45 nm or smaller IC fabrication nodes), gate current leakage increases as the gate insulator 124 thickness reaches scaling limits. In such cases, a commonly preferred choice for the gate structure 106 is a high dielectric constant (high-κ) replacement metal gate (RMG) structure. The high-κ material may be, for example, hafnium oxide, HfO₂. A high-κ RMG structure is easy to integrate with transistors built upon SOI substrates as well as non-silicon high-mobility materials, such as Ge, carbon nanotubes, and III-V substrates.

FIG. 3A is a cross-sectional view of high-κ RMG structure taken along the X dimension of a FET. FIG. 3B is a cross-sectional view of high-κ RMG structure taken along the Y dimension of a FET. The conventional BOX layer 130 and substrate 132 are omitted to reduce clutter. In place of polysilicon for the gate material 126 in FIGS. 1B and 1C, the illustrated example shows a multi-layer gate structure 106 comprising an interface insulator (e.g., a thin SiO₂ layer) 140, a high-κ material 142 such as HfO₂, an nFET work function layer 144 such as tantalum (Ta), a barrier layer 146 such as titanium nitride (TiN), and a low-resistance gate contact interface 148 such as tungsten (W).

Referring back to FIG. 1A, regardless of the type of gate structure 106, the SiO₂ backfilling and LOCOS isolation techniques, as well as similar processes, leave the two opposing width-wise edges 116 (indicated by the bold lines within the reference ovals 118) of the nFET conduction channel 113 in contact with SiO₂. During IC fabrication processing for the nFET 100, boron dopant implanted within the P-type silicon island 102 under the gate structure 106 (i.e., within the FET conduction channel 113) migrates from the silicon at the edges 116 of the nFET conduction channel 113 into the adjacent SiO₂. See also FIG. 3B, showing subregions 150 (bounded by dashed ovals) within the doped Si region 122 from which boron (for an nFET) migrates out and into the adjacent SiO₂ STI structures 120, as indicated by the arrows M.

Again referring to FIG. 1A, dopant migration causes the boron concentration in the silicon at the edges 116 of the FET to be lower than in the central region of the conduction channel 113 (the central region is approximately encompassed by the dotted-line reference box 119). The boron depletion at the edges 116 of an nFET 100 results in a reduction of threshold voltage at the edges 116 of the conduction channel 113 due to the band gap at the edges 116 being bent downward, typically by several tenths of a volt (for reference, the bandgap of silicon is about 1 V). Drain leakage current, Id_{OFF}, increases approximately at the rate of a decade of current for every 67 mV of band bending. Hence, boron depletion at the edges 116 of an nFET 100 may cause the leakage current at the edges 116 to increase by multiple orders of magnitude as compared to a flat profile with no boron depletion.

This phenomenon has been known since the earliest utilization of SOI for substrates, and results in a lower threshold voltage, V_{T}, at the edges 116 of the nFET 100—so-called “edge transistors”—thereby increasing leakage current (especially since there are typically two edges per transistor, as shown in FIG. 1A). Indeed, from this perspective, the nFET 100 may be modeled as three parallel transistors: a central conduction channel spanning between the source and drain regions and defining a central conduction channel FET (C³FET) having a threshold voltage V_{TC}, and two edge conduction channels spanning between the source and drain regions and defining edge FETs (EFETs) having lower threshold voltages V_{TE}. Due to their lower V_{TE}, the two EFETs begin conducting current through the two edge conduction channels before the V_{TC} of the C³FET is reached, resulting in increased leakage at the edges of the device. This edge leakage often dominates the total leakage of an nFET, which in turn can increase standby power consumption of such FETs by an order of magnitude or more and thus increase overall power consumption of any systems using such nFETs. This edge leakage problem may also be seen in pFETs fabricated on SOI substrates. Uncontrolled EFETs result in a worse FET ON/OFF ratio and make designing analog and digital circuits more difficult.

While the extent of the EFETs of an nFET involves the length of the gate structure 106 at the edges 116 of the nFET 100 as well as doping concentrations along that length and permeating to an extent about the width (i.e., laterally) and depth of the nFET at those edges 116, it is convenient to refer to just the edges 116 as being EFETs. Thus, for purposes of this disclosure, the edges 116 indicated by bold lines in FIG. 1A can be considered as defining the EFETs of the illustrated nFET 100 unless otherwise characterized.

Attempts have been made to reduce EFET leakage by increasing the length of the gate structure 106 at the EFETs 116 of an nFET 100, thus lengthening the corresponding edge transistors of the nFET 100 relative to the length L of the central portion of the conduction channel 113 of the nFET 100, and/or by setting back the edge transistors 116 of the main channel from the silicon island 102. However, these approaches have numerous disadvantages, including insufficient reduction in leakage current, some increase in area and total gate capacitance, and a reduction in drive current I_{ON}, especially in minimum width transistors.

Several solutions to the EFET problem have been described in U.S. Pat. No. 10,115,787 B1, issued Oct. 30, 2018, entitled “Low Leakage FET”, assigned to the assignee of the present invention, the contents of which are incorporated herein by reference. Disclosed embodiments include, for example, nFET designs in which the V_{TE} of the EFETs is increased relative to the V_{TC} of the C³FET by changing the work function of the gate structure overlying the EFETs, primarily by adding P+ implant regions over the edges 116 of an nFET. However, not disclosed are solutions to the EFET problem applicable to high-κ RMG structures like the type described above, a problem addressed by the present invention.

### SUMMARY

The present invention encompasses FET designs, and in particular NMOSFET (“nFET”) designs based on SOI fabrication technology, that exhibit low leakage in the presence of the edge transistor phenomenon. Embodiments of the invention include nFET designs in which the threshold voltage V_{TE} of the edge FETs (EFETs) is increased to a level that is at least equal to, and may exceed, the threshold voltage V_{TC} of the central conduction channel FET (C³FET) using a novel dual work function configuration of a high dielectric constant (high-κ) replacement metal gate (RMG) structure.

A first embodiment encompasses a FET including a replacement metal gate structure overlying a doped silicon region, the replacement metal gate structure including: an interface insulator formed over the doped silicon region; a high dielectric constant material formed over the interface insulator; an N-type work function material overlaying and in contact with a central portion of the high dielectric constant material; and a P-type work function material overlaying and in contact with at least one edge portion of the high dielectric constant material.

A second embodiment encompasses a FET fabricated on a silicon-on-insulator substrate, the FET including: an isolated silicon island; a source region and a drain region spaced apart within the isolated silicon island; a central conduction channel between the source and drain regions and having a threshold voltage V_{TC}; at least one edge conduction channel between the source and drain regions and having a threshold voltage V_{TE}; a replacement metal gate structure overlying the isolated silicon island between the source and drain regions and positioned over the central conduction channel and the at least one edge conduction channel, the gate structure including: an interface insulator formed over the central conduction channel and the at least one edge conduction channel; a high dielectric constant material formed over the interface insulator and having a central portion corresponding to the central conduction channel and at least one edge portion of the high dielectric constant material corresponding to the at least one edge conduction channel; an N-type work function material overlaying and in contact with the central portion of the high dielectric constant material; and a P-type work function material overlaying and in contact with the at least one edge portion of the high dielectric constant material, wherein the P-type work function material increases V_{TE} sufficiently to be approximately equal to or greater than V_{TC}.

The details of one or more embodiments of the invention are set forth in the accompanying drawings and the description below. Other features, objects, and advantages of the invention should be apparent from the description and drawings, and from the claims.

### DESCRIPTION OF THE DRAWINGS

FIG. 1A is a top plan view of the layout of a typical prior art N-type MOSFET (“nFET”) based on SOI fabrication technology.

FIG. 1B is a cross-sectional view of the nFET along line A-A of FIG. 1A.

FIG. 1C is a cross-sectional view of the nFET along line B-B of FIG. 1A.

FIG. 2 is a perspective view of an nFET similar to the nFET of FIG. 1A.

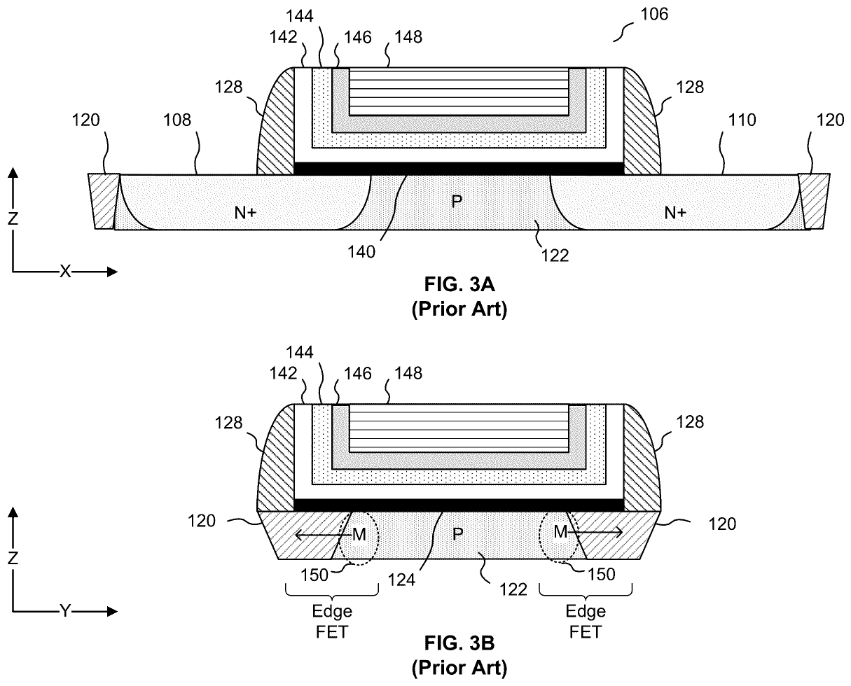

FIG. 3A is a cross-sectional view of high-κ RMG structure taken along the X dimension of a FET.

FIG. 3B is a cross-sectional view of high-κ RMG structure taken along the Y dimension of a FET.

FIG. 4A is a cross-sectional view of a first embodiment of high-κ RMG structure having a dual work function configuration, taken along the Y dimension of a FET.

FIG. 4B is a cross-sectional view of a second embodiment of high-κ RMG structure having a dual work function configuration, taken along the Y dimension of a FET.

FIG. 4C is a cross-sectional view of a third embodiment of high-κ RMG structure having a dual work function configuration, taken along the Y dimension of a FET.

FIG. 4D is a cross-sectional view of a fourth embodiment of high-κ RMG structure having a dual work function configuration, taken along the Y dimension of a FET.

FIG. 5 is a chart showing the work function of various metal elements.

FIGS. 6A-6J are cross-sectional views taken along the Y dimension of a FET of various stages of fabrication of a high-κ RMG structure having a dual work function configuration and made using an “NWF” first fabrication approach.

FIGS. 7A-7E are cross-sectional views taken along the Y dimension of a FET of various stages of fabrication of a high-κ RMG structure having a dual work function configuration and made using an “NWF” last fabrication approach.

FIG. 8 is a top plan view of a substrate that may be, for example, a printed circuit board or chip module substrate (e.g., a thin-film tile).

Like reference numbers and designations in the various drawings indicate like elements unless the context requires otherwise.

### DETAILED DESCRIPTION

The present invention encompasses FET designs, and in particular NMOSFET (“nFET”) designs based on SOI fabrication technology, that exhibit low leakage in the presence of the edge transistor phenomenon. Embodiments of the invention include nFET designs in which the threshold voltage V_{TE} of the edge FETs (EFETs) is increased to a level that is at least equal to, and may exceed, the threshold voltage V_{TC} of the central conduction channel FET (C³FET) using a novel dual work function configuration of a high dielectric constant (high-κ) replacement metal gate (RMG) structure.

### Dual Work Function Configuration of a High-κ RMG Structure

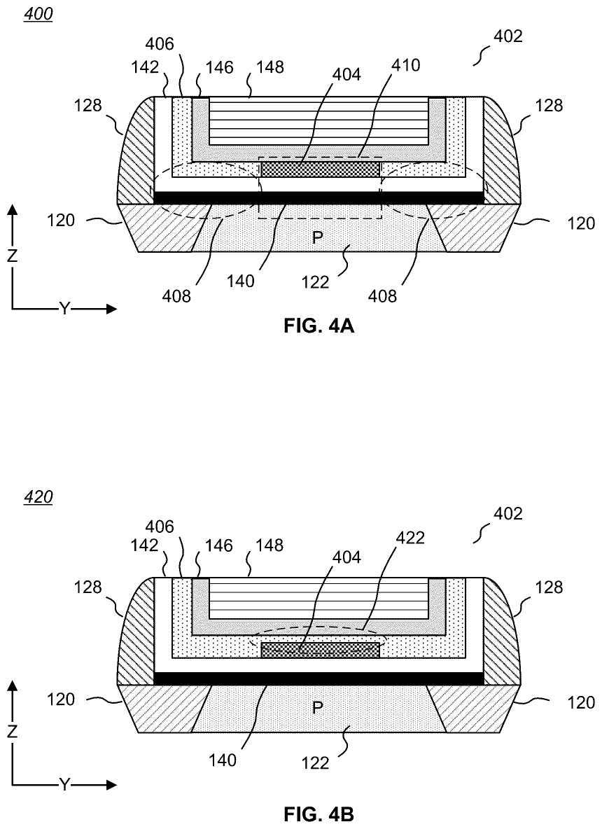

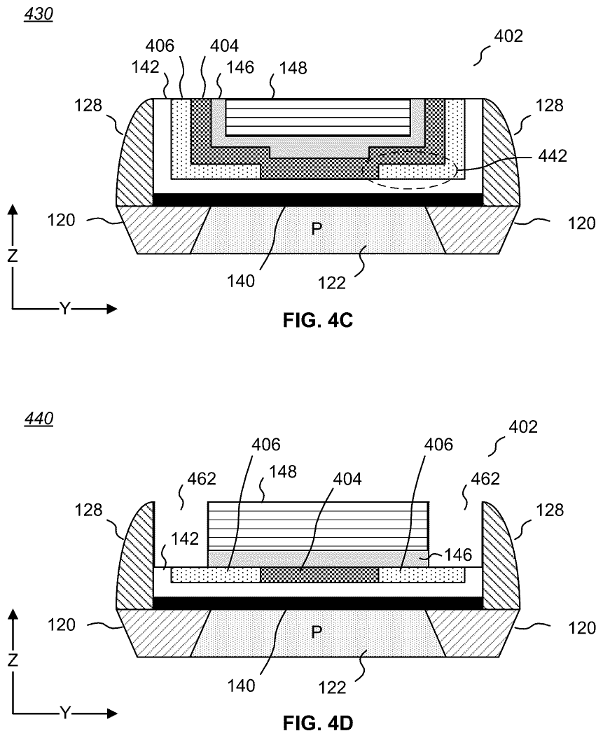

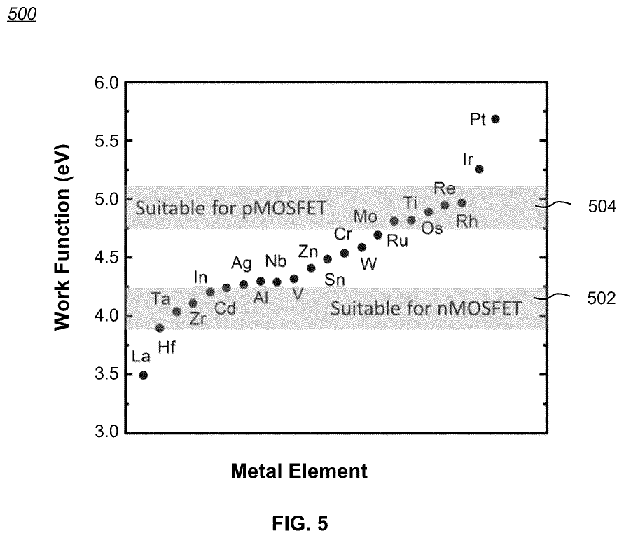

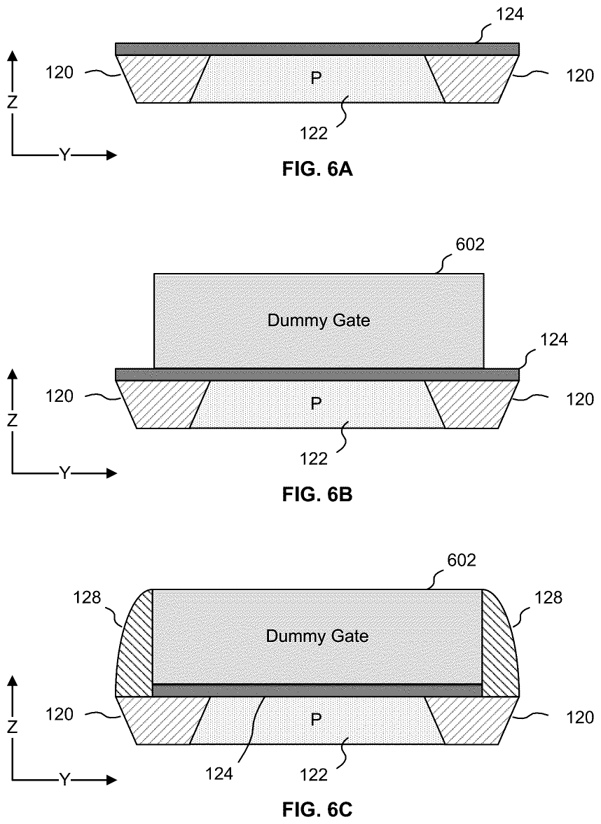

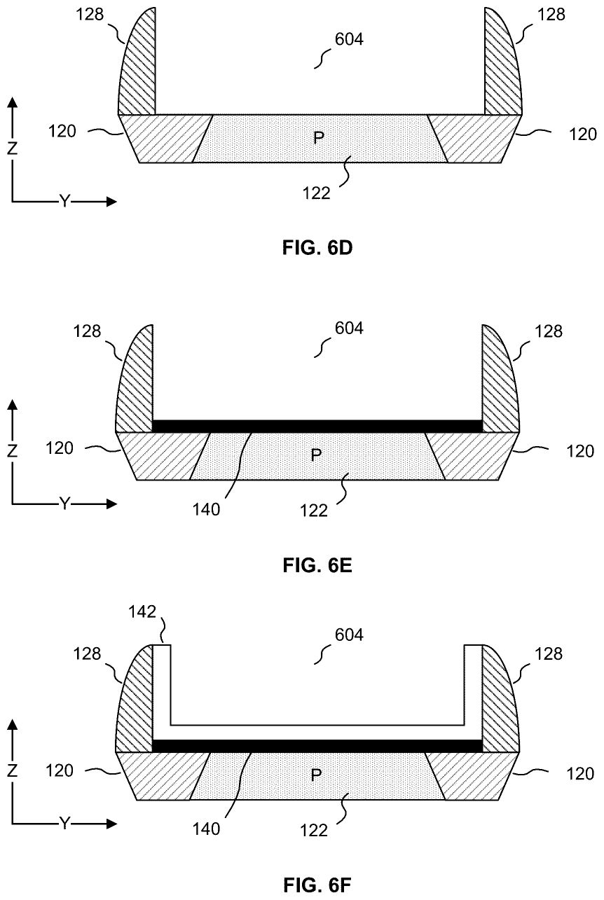

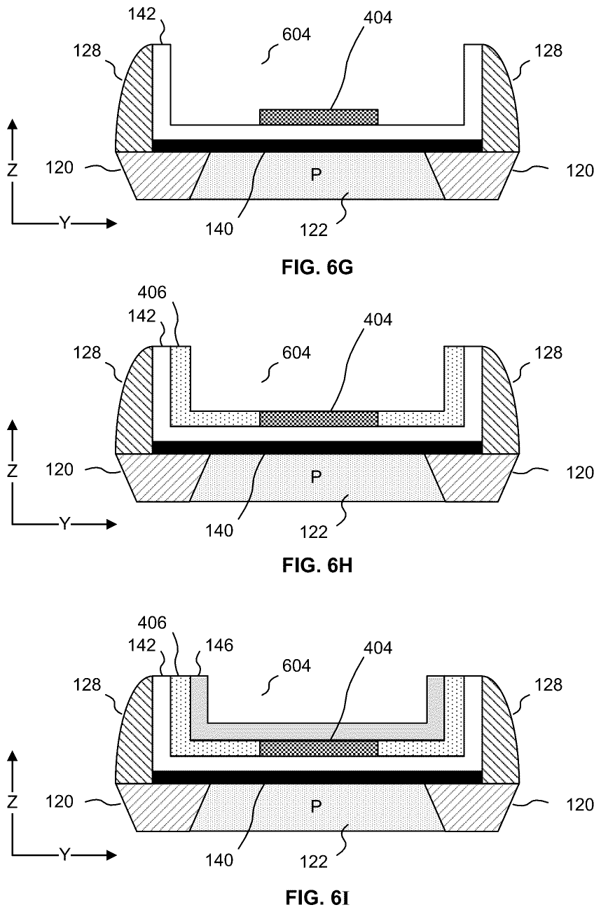

FIG. 4A is a cross-sectional view of a first embodiment of high-κ RMG structure 400 having a dual work function configuration, taken along the Y dimension of a FET. The illustrated high-κ RMG structure 400 may be used in place of the high-κ RMG structure shown in FIGS. 3A and 3B. Elements in common with the high-κ RMG structure shown in FIGS. 3A and 3B bear the same reference numbers. Thus, the illustrated example shows a multi-layer gate structure 402 between offset spacers 128 and overlaying isolation structures 120 and a doped Si region 122. The multi-layer gate structure 402 includes an interface insulator (e.g., a thin SiO₂ layer) 140, a high-κ material 142 (e.g., HfO₂ or any other suitable high-κ material), a barrier layer 146 (e.g., titanium nitride TiN or any other suitable barrier material), and a gate contact interface 148 (e.g., tungsten W or any other suitable contact material). A substrate, BOX layer, and other portions of an Si Active Region are omitted to reduce clutter.

A distinct difference shown in FIG. 4A is a dual work function layer that includes (1) an N-type work function (NWF) material 404 overlaying and in contact with a central portion of the high-κ material 142 and (2) a P-type work function (PWF) material 406 overlaying and in contact with the edge portions of the high-κ material 142. Thus, the PWF material 406 determines the V_{TE} of the EFETs (shown circumscribed by dashed ovals 408 in FIG. 4A), while the NWF material 404 determines the V_{TC} of the C³FET (shown circumscribed by the dashed rectangle 410).

FIG. 4B is a cross-sectional view of a second embodiment of high-κ RMG structure 420 having a dual work function configuration, taken along the Y dimension of a FET. Similar in most aspects to the embodiment shown in FIG. 4A, the illustrated configuration shows an “NWF” first fabrication approach in which the NWF material 404 is formed over the central portion of the high-κ material 142, followed by formation of the PWF material 406. The PWF material 406 may overlay the NWF material 404 as shown within dashed oval 422. Since the work function is determined by the nature of the work function material in contact with the high-κ material 142, the overlap of PWF material 406 on the NWF material 404 does not affect the V_{TC} of the C³FET.

FIG. 4C is a cross-sectional view of a third embodiment of high-κ RMG structure 430 having a dual work function configuration, taken along the Y dimension of a FET. Similar in most aspects to the embodiment shown in FIG. 4A, the illustrated configuration shows an “NWF” last fabrication approach in which the PWF material 406 is formed over the central portion of the high-κ material 142, a central portion of the PWF material 406 is then removed (e.g., by etching), followed by formation of the NWF material 404. The NWF material 404 may overlay part of the PWF material 406 as shown within dashed oval 442. Since the work function is determined by the nature of the work function material in contact with the high-κ material 142, the overlap of NWF material 404 on the PWF material 406 does not affect the V_{TE} of the EFETs.

FIG. 4D is a cross-sectional view of a fourth embodiment of high-κ RMG structure 440 having a dual work function configuration, taken along the Y dimension of a FET. Similar in most aspects to the embodiment shown in FIG. 4A, the illustrated configuration shows that air gaps 462 have been formed, such as by masking and etching, between the offset spacers 128 and a central stack comprising portions of the barrier layer 146 and the gate contact interface 148. In the illustrated example, the air gaps 462 preferably extend down to the high-κ material 142 and the PWF material 406, but other stopping points may be selected. The air gaps 462 help lower the gate- source capacitance C_{GS} and the gate-drain capacitance C_{GD} for FET switches and transistor devices, which is particularly useful for RF products.

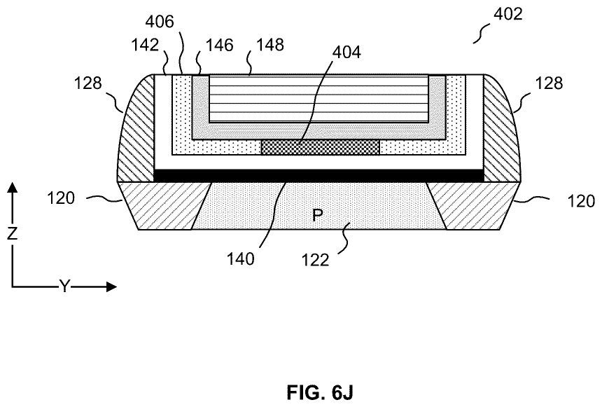

FIG. 5 is a chart 500 showing the work function of various metal elements. A first band 502 indicates metals that have a work function between about 3.8 eV and about 4.25 eV and are generally suitable as an NWF material 404. Thus, candidates for the NWF material 404 include hafnium, tantalum, zirconium, indium, and cadmium. A second band 504 indicates metals that have a work function between about 4.75 eV and about 5.2 eV and are generally suitable as a PWF material 406. Thus, candidates for the PWF material 406 include molybdenum, osmium, titanium, rhenium, and ruthenium. Various alloys of these metals and other materials may also be used to provide suitable NWF and PWF materials compatible with N-type and P-type FETs, respectively.

With the PWF material 406 in contact with the edges of the high-κ material 142 above the doped Si region 122, the work function ΦMF of the multi-layer gate structure 402 may be increased by at least about 0.3 V, and often by more than about 0.5 V. This increase in Φ_{MF} may raise the V_{TE} of the EFET portions of the gate structure 402 by an amount at least equal to Φ_{MF}. Depending on the V_{TC} of the C³FET and the specific PWF material 406 selected, the V_{TE} of the EFETs may raise to a level at or even above the V_{TC} of the C³FET, thereby ensuring that the edge transistor standby current leakage will be equal to or significantly reduced as compared to the center channel region.

### Example Fabrication Methods

A number of different methods may be used to fabricate high-κ RMG structures having a dual work function configuration such as shown in FIGS. 4A-4D. The initial steps of such methods may be common to an “NWF” first fabrication approach and an “NWF” last fabrication approach.

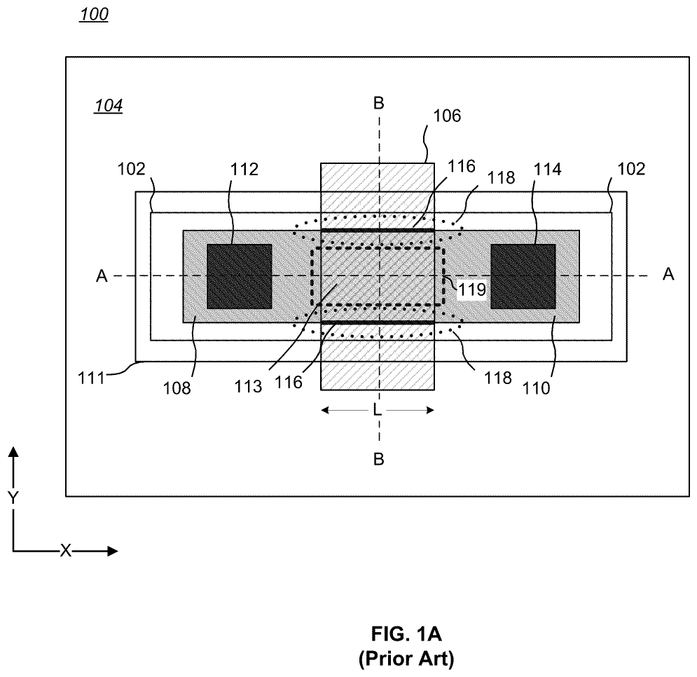

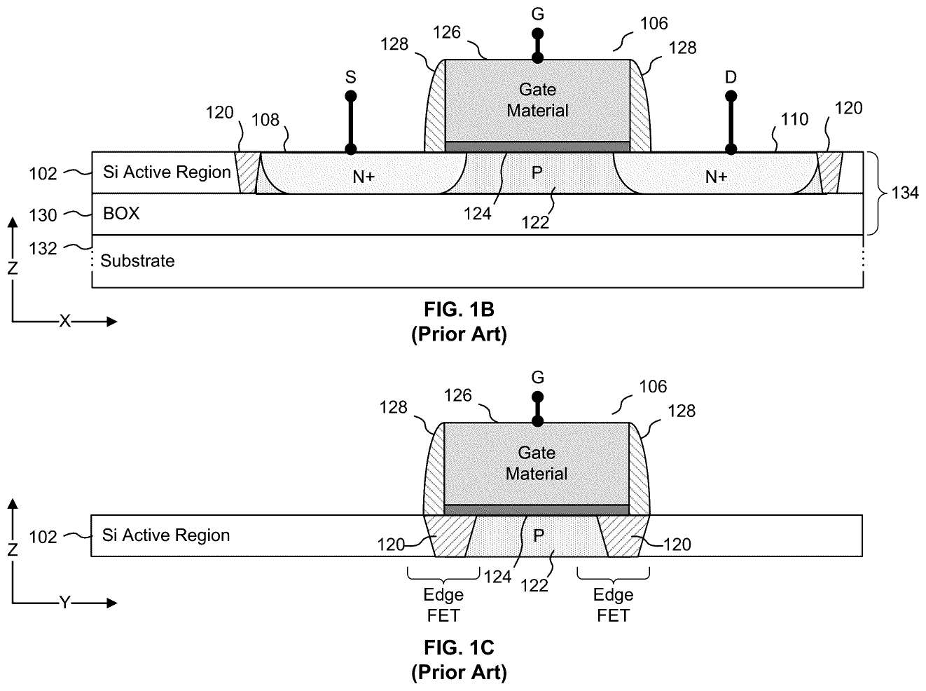

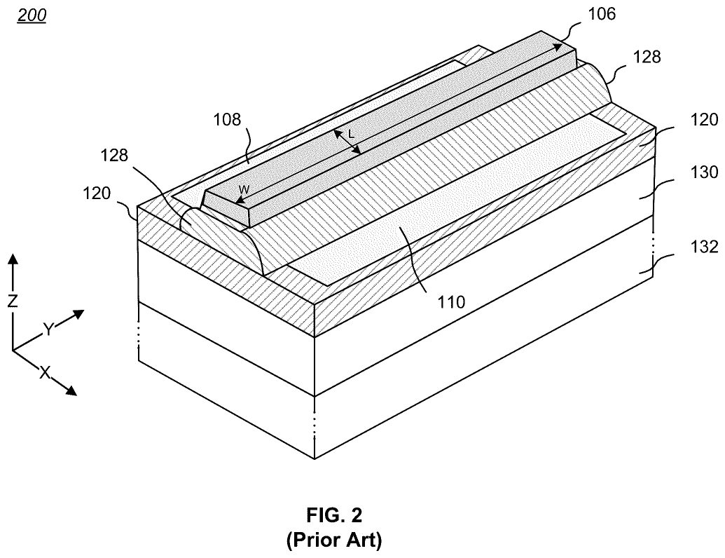

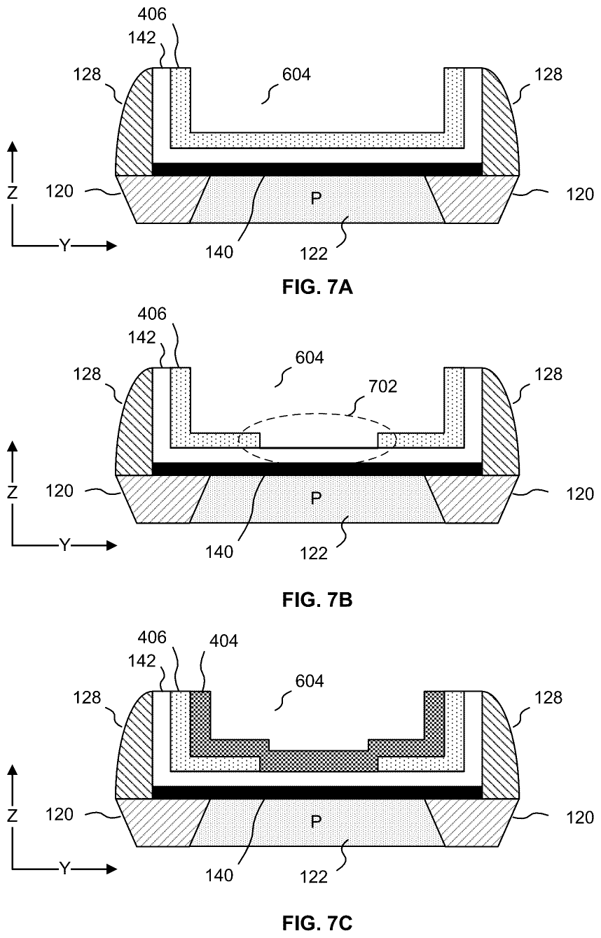

For example, FIGS. 6A-6J are cross-sectional views taken along the Y dimension of a FET of various stages of fabrication of a high-κ RMG structure having a dual work function configuration and made using an “NWF” first fabrication approach. A conventional BOX layer 130 and substrate 132 (see FIG. 1B) are omitted to reduce clutter. The basic concepts illustrated include: forming an initial “dummy” gate to provide structure for the replacement metal gate; removing the dummy gate to create a recess for the RMG structure; and building up the high-κ RMG structure so as to include an NWF material 404 overlaying and in contact with the central portion of the high-κ material 142 and PWF material 406 overlaying and in contact with the edge portions of the high-κ material 142. Many of the reference numbers in FIGS. 6A-6J correspond to the elements shown in FIGS. 4A-4D where applicable.

More specifically, FIG. 6A shows deposition of a gate insulator 124 over a previously prepared SOI substrate having a substructure that includes a doped Si region 122 (P-type in this example) and associated isolation structures 120 (e.g., STI structures) formed within the Si Active Region of the substructure. FIG. 6B shows formation of a dummy gate 602 on the gate insulator 124 and over the doped Si region 122. The dummy gate 602 may be conventional polysilicon. FIG. 6C shows formation of offset spacers 128 along the sides of the dummy gate 602. The offset spacers 128 may comprise, for example, SiO₂, a Low-K dielectric, SiN, or SiON.

Replacement metal gates literally replace a dummy gate. Accordingly, FIG. 6D shows that the dummy gate 602 and the gate insulator 124 that were bounded by the offset spacers 128 have been removed, such as by dry etching, leaving a recess 604. FIG. 6E shows formation of an interface insulator 140, which may be, for example, a thin SiO₂ layer formed, for example, by oxidation of the exposed portions of the doped Si region 122 and associated isolation structures 120. FIG. 6F shows deposition of a high-κ material 142 (e.g., HfO₂) on the floor and walls of the recess 604, such as by atomic layer deposition (ALD) which provides a high conformal and quality film deposition.

FIG. 6G shows formation of an NWF material 404 over and in contact with the central portion (with respect to the doped Si region 122) of the high-κ material 142. The area in which the NWF material 404 is formed may be defined, for example, by conventional masking and etching, with the NWF material 404 deposited by ALD or chemical vapor deposition (CVD) and the masking material then removed. FIG. H shows formation of a PWF material 406 over and in contact with the edge portions (with respect to the doped Si region 122) of the high-κ material 142. Again, the areas in which the PWF material 406 is formed may be defined, for example, by conventional masking and etching, with the PWF material 406 deposited by ALD or CVD and the masking material then removed. Alternatively, because the work function is determined by the nature of the work function material in contact with the high-κ material 142, masking off the NWF material 404 may not be necessary, since overlap of the PWF material 406 on the NWF material 404 would not affect the V_{TC} of the C³FET (see also the discussion of FIG. 4B above).

FIG. 6I shows deposition of a barrier layer 146 (e.g., TiN) on the floor and walls of the (diminishing) recess 604, for example, by using ALD or CVD. FIG. 6J shows filling the remainder of the recess 604 with a gate contact interface 148, such as tungsten. Additional front-end-of-line (FEOL) steps, such as chemical-mechanical polishing (CMP), may be performed to finalize fabrication of the IC prior to formation of a superstructure of metallization layers and conductive vias in a back-end-of-line (BEOL) process.

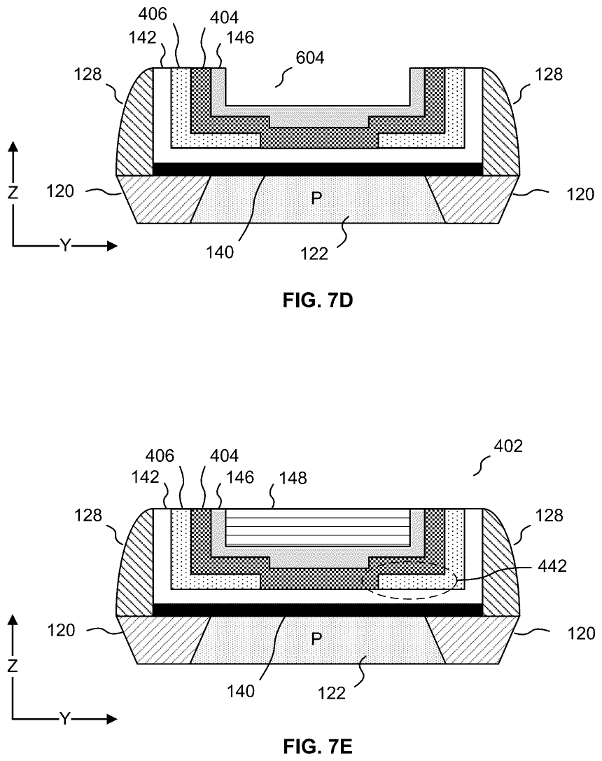

FIGS. 7A-7E are cross-sectional views taken along the Y dimension of a FET of various stages of fabrication of a high-κ RMG structure having a dual work function configuration and made using an “NWF” last fabrication approach. The “NWF” last fabrication approach performs the same fabrication steps shown in FIGS. 6A-6F. FIG. 7A shows that, after deposition of the high-κ material 142 on the floor and walls of the recess 604, PWF material 406 is deposited on the floor and walls of the recess 604, such as by ALD or CVD, over and in contact with the high-κ material 142.

FIG. 7B shows that a gap 702 (indicated by dashed oval) has been formed within the PWF material 406 over the central portion of the doped Si region 122, such as by conventional masking and etching. FIG. 7C shows deposition of an NWF material 404 on the floor and walls of the recess 604 and within the defined gap 702 over and in contact with the central portion of the high-κ material 142. The NWF material 404 may be deposited by ALD or CVD.

FIG. 7D shows deposition of a barrier layer 146 (e.g., TiN) on the floor and walls of the (diminishing) recess 604, for example, by using ALD or CVD. FIG. 7E shows filling the remainder of the recess 604 with a gate contact interface 148, such as tungsten. Again, additional FEOL steps, such as CMP, may be performed to finalize fabrication of the IC prior to formation of a superstructure of metallization layers and conductive vias in a BEOL process.

It should be appreciated that additional layers may be included within a multi-layer gate structure 402 for particular applications and/or manufacturing processes. Further, in some applications, it may be sufficient to form PWF material 406 over only one FET of the gate structure 402. The inventive multi-layer gate structure 402 may be readily adapted for use with P-type MOSFETs (“pFETs”) as well.

### Circuit Embodiments

Circuits and devices in accordance with the present invention may be used alone or in combination with other components, circuits, and devices. Embodiments of the present invention may be fabricated as complete integrated circuits (ICs), which may be encased in IC packages and/or in modules for ease of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

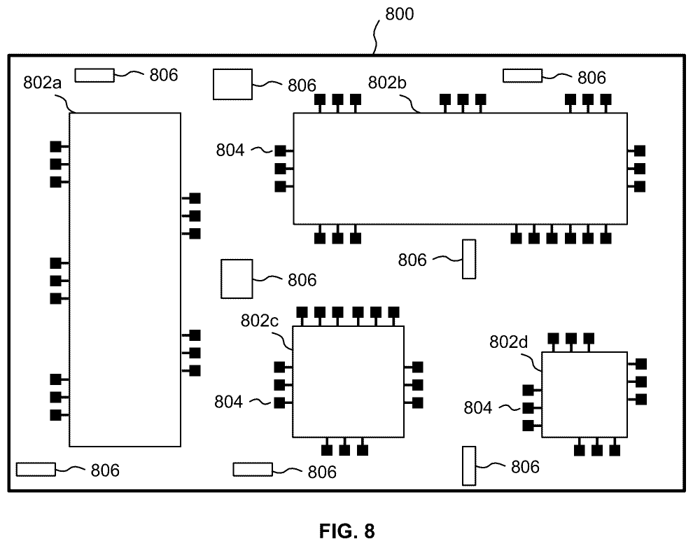

As one example of further integration of embodiments of the present invention with other components, FIG. 8 is a top plan view of a substrate 800 that may be, for example, a printed circuit board or chip module substrate (e.g., a thin-film tile). In the illustrated example, the substrate 800 includes multiple ICs 802a-802d having terminal pads 804 which would be interconnected by conductive vias and/or traces on and/or within the substrate 800 or on the opposite (back) surface of the substrate 800 (to avoid clutter, the surface conductive traces are not shown and not all terminal pads are labelled). The ICs 802a-802d may embody, for example, signal switches, active and/or passive filters, amplifiers (including one or more LNAs), and other circuitry. For example, IC 802b may incorporate one or more instances of a low-leakage RMG FET like those disclosed in FIGS. 4A-4D.

The substrate 800 may also include one or more passive devices 806 embedded in, formed on, and/or affixed to the substrate 800. While shown as generic rectangles, the passive devices 806 may be, for example, filters, capacitors, inductors, transmission lines, resistors, antennae elements, transducers (including, for example, MEMS-based transducers, such as accelerometers, gyroscopes, microphones, pressure sensors, etc.), batteries, etc., interconnected by conductive traces on or in the substrate 800 to other passive devices 806 and/or the individual ICs 802a-802d. The front or back surface of the substrate 800 may be used as a location for the formation of other structures.

### System Aspects

The present invention improves reduces EFET leakage and thus reduces the total leakage of an nFET, resulting in a reduction of standby power consumption of such nFETs by an order of magnitude or more and thus decreasing overall power consumption of any systems using such nFETs. As a person of ordinary skill in the art will understand, a system architecture is beneficially impacted by the current invention in critical ways, including lower power and longer battery life.

A dual work function configuration of a high-κ RMG structure in accordance with the present invention is easy to integrate with transistors built upon SOI substrates as well as non- silicon high-mobility materials, such as Ge, carbon nanotubes, and III-V semiconductor substrates. III-V semiconductors comprise semiconductor alloys that include an element having three (III) valence electrons and an element having five (V) valence electrons. Group III elements include boron (B), aluminum (Al), gallium (Ga), and indium (In), while group V elements include nitrogen (N), phosphorous (P), arsenic (As), and antimony (Sb).

Embodiments of the present invention are useful in a wide variety of larger radio frequency (RF) circuits and systems for performing a range of functions, including (but not limited to) impedance matching circuits, RF power amplifiers, RF low-noise amplifiers (LNAs), phase shifters, attenuators, antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G, 6G, and WiFi (e.g., 802.11a, b, g, ac, ax, be) protocols, as well as other radio communication standards and protocols.

### Fabrication Technologies & Options

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHZ. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as bipolar junction transistors (BJTs), BiCMOS, LDMOS, BCD, using 2-D, 2.5-D, and 3-D structures. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

### Conclusion

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1. A FET including a replacement metal gate structure overlying a doped silicon region, the replacement metal gate structure including:
(a) an interface insulator formed over the doped silicon region;
(b) a high dielectric constant material formed over the interface insulator;
(c) an N-type work function material overlaying and in contact with a central portion of the high dielectric constant material; and
(d) a P-type work function material overlaying and in contact with at least one edge portion of the high dielectric constant material.

2. The invention of claim 1, wherein the FET is fabricated on a silicon substrate having a silicon active region formed on an insulating layer of the silicon substrate.

3. The invention of claim 1, wherein the replacement metal gate structure further includes a barrier layer overlaying the N-type work function material and the P-type work function material.

4. The invention of claim 3, wherein the replacement metal gate structure further includes a gate contact overlaying the barrier layer.

5. The invention of claim 1, wherein the high dielectric constant material comprises hafnium oxide.

6. The invention of claim 1, wherein the N-type work function material has a work function between about 3.8 eV and about 4.25 eV.

7. The invention of claim 1, wherein the N-type work function material is one of hafnium, tantalum, zirconium, indium, or cadmium, or an alloy of thereof.

8. The invention of claim 1, wherein the P-type work function material has a work function between about 4.75 eV and about 5.2 eV.

9. The invention of claim 1, wherein the P-type work function material is one of molybdenum, osmium, titanium, rhenium, or ruthenium, or an alloy of thereof.

10. The invention of claim 1, wherein the edge portions of the high dielectric constant material and the doped silicon region comprise edge transistors having a threshold voltage V_{TE} and the P-type work function material increases the threshold voltage V_{TE} by at least about 0.3 V.

11. The invention of claim 1, wherein the P-type work function material overlies the N-type work function material.

12. The invention of claim 1, wherein the N-type work function material overlies the P-type work function material.

13. The invention of claim 1, wherein the replacement metal gate structure further includes offset spacers surrounding at least the interface insulator, the high dielectric constant material, the N-type work function material, and the P-type work function material.

14. The invention of claim 13, wherein the replacement metal gate structure further includes:
(a) a barrier layer overlaying the N-type work function material and the P-type work function material; and
(b) a gate contact overlaying the barrier layer.

15. The invention of claim 13, wherein the replacement metal gate structure further includes air gaps between the offset spacers and the barrier layer and the gate contact.

16.-55. (canceled)
